(19) United States
(12) Patent Application Publication
(10) Pub. No.: US 2010/0110641 A1
(43) Pub. Date: May 6, 2010

(54) POWER SUPPLY APPARATUS

(76) Inventor: Tetsuhide Okahashi, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/574,973

(22) Filed: Oct. 7, 2009

(30) Foreign Application Priority Data
Oct. 31, 2008 (JP) 2008-281889(P)

(51) Int. Cl. H05K 7/20

(52) U.S. Cl. 361/720

(57) ABSTRACT

A power supply apparatus includes a printed circuit board having the longitudinal direction and including first and second regions where AC and DC circuit components are mounted respectively. A first heat dissipation plate and a second heat dissipation plate provided to stand respectively in the first and second regions each include, as seen in a plan view, a linear first straight portion and two second straight portions extending respectively from the two ends of the first straight portion in opposite directions respectively and in the longitudinal direction. Respective first straight portions of the first and second heat dissipation plates are opposite to each other, and one of the second straight portions of the first heat dissipation plate and one of the second straight portions of the second heat dissipation plate are partially opposite to each other.

This nonprovisional application is based on Japanese Patent Application No. 2008-281889 filed on Oct. 31, 2008 with the Japan Patent Office, the entire contents of which are hereby incorporated by reference.

### BACKGROUND OF THE INVENTION

1. Field of the Invention

The present invention relates to a power supply apparatus, and particularly to a shape of a heat dissipation plate and a structure for attaching the heat dissipation plate to a printed circuit board.

2. Description of the Background Art

A power supply circuit substrate is restricted in shape and size depending on where the substrate is installed. Thus, in addition to square substrates with stable mechanical strength, rectangular substrates are also employed. Some rectangular substrates are long and thin in shape with a ratio of the longer side to the shorter side of approximately 6:1. Such a long and thin rectangular substrate is likely to warp in the longitudinal direction of the substrate. The occurrence of warpage causes stress on a chip-shaped component mounted on the substrate, resulting in a problem that a crack is opened. Therefore, in some cases, only a component with leads that is less likely to be influenced by warpage of the substrate is mounted, as an electronic component, on the substrate. FIG. 10 is a schematic plan view showing a state where one heat dissipation plate is placed on a substrate in a conventional power supply apparatus. In some cases, as shown in FIG. 10, in order to reduce warpage of a substrate 1, one long heat dissipation plate 70 is placed in the longitudinal direction on substrate 1.

Japanese Patent Laying-Open No. 06-196837 and Japanese Utility Model Laying-Open No. 05-033497 disclose a mounting apparatus with which warpage of a substrate is reduced by placing a heat dissipation plate on the substrate. A mounting apparatus for a heat generating component disclosed in Japanese Patent Laying-Open No. 06-196837 places a heat dissipation plate over the upper surface of a printed circuit board substantially in parallel with the upper surface of the printed circuit board, with a space of a predetermined width between the printed circuit board and the heat dissipation plate, and mounts a heat generating device on the upper surface of the heat dissipation plate in parallel with the upper surface thereof. An inverter power supply unit for a high-frequency heating apparatus disclosed in Japanese Utility Model Laying-Open No. 05-033497 has a thick wall provided to stand perpendicularly to a printed circuit board, and a heat dissipation fin with fin blades formed perpendicularly to the thick wall is attached. Further, a rectifying device, a switching device and a flywheel diode that are heat generating components of the inverter power supply circuit are attached to the thick wall.

In the case where only a component with leads is mounted on a substrate, as an electronic component to be mounted on the substrate, this component larger in size than a chip-shaped component hinders the substrate from being made compact. In the case where one long heat dissipation plate is placed in the longitudinal direction of a substrate, it is necessary to connect the heat dissipation plate and a mounted component with an insulation sheet interposed therebetween, for example, in order to conform to the requirements of the Electrical Appliance and Material Safety Law. Specifically, as for a power supply apparatus, it is required that an input side and an output side of the power supply apparatus have to be insulated from each other. Therefore, usually the primary side and the secondary side of a transformer are insulated from each other to satisfy the requirement of the Electrical Appliance and Material Safety Law. If an alternating current (AC) circuit component and a direct current (DC) circuit component are connected to the same heat dissipation plate, these components are electrically connected via the heat dissipation plate. Thus, in order to prevent the heat dissipation plate and the AC circuit component or the DC circuit component from being directly connected to each other, they are connected with an insulation sheet interposed therebetween. A problem in this case is that the heat dissipation ability of the heat dissipation plate is deteriorated.

Regarding the mounting apparatus for a heat generating component disclosed in Japanese Patent Laying-Open No. 06-196837, the heat dissipation plate is placed substantially in parallel with the substrate. Thus, if the substrate area is restricted, the area of the heat dissipation plate that can be placed over the substrate is accordingly smaller, and sufficient heat dissipation ability cannot be ensured. Regarding the inverter power supply unit for a high-frequency heating apparatus disclosed in Japanese Utility Model Laying-Open No. 05-033497 as well, if the substrate area is restricted, the space where the heat dissipation fin can be placed is accordingly smaller, and sufficient heat dissipation ability cannot be ensured.

### SUMMARY OF THE INVENTION

The present invention has been made in view of the above-described problems, and an object of the invention is to provide a power supply apparatus in which warpage of a printed circuit board, even if the printed circuit board has a high ratio of the longer side to the shorter side, can be effectively prevented, and a large area can be ensured for mounting a chip component, while heat can be efficiently released.

A power supply apparatus according to the present invention converts alternating current to direct current. The power supply apparatus includes: a printed circuit board having a first region where an alternating current circuit component is mounted and a second region where a direct current circuit component is mounted, and having a longitudinal direction; a first heat dissipation plate provided to stand in the first region on the printed circuit board; and a second heat dissipation plate provided to stand in the second region on the printed circuit board. The first heat dissipation plate and the second heat dissipation plate each have a linear first straight portion and two second straight portions extending respectively from two ends of the first straight portion in respective directions opposite to each other as seen in a plan view. At least a part of the first straight portion of the first heat dissipation plate and at least a part of the first straight portion of the second heat dissipation plate are opposite to each other, and at least a part of one of the second straight portions of the first heat dissipation plate and at least a part of one of the second straight portions of the second heat dissipation plate are opposite to each other. The second straight portions are each placed in the longitudinal direction of the printed circuit board.

In accordance with the present invention, the heat dissipation plates having a predetermined shape are provided to stand on the printed circuit board, so that warpage of the printed circuit board, even if the printed circuit board has a high ratio of the longer side to the shorter side, can be effectively prevented, and a large area can be ensured for mounting a chip-shaped component. Further, the heat dissipation plates are respectively connected directly with the AC circuit component and the DC circuit component, so that the heat generated from the AC and DC circuit components can be efficiently released.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view showing arrangement of heat dissipation plates of a power supply apparatus according to a first embodiment of the present invention.

FIG. 2 is a schematic plan view showing fixture portions where heat dissipation plates and a printed circuit board of a power supply apparatus are joined to each other according to the first embodiment.

FIG. 3 is a schematic plan view showing a modification of fixture portions where heat dissipation plates and a printed circuit board of a power supply apparatus are joined to each other according to the first embodiment.

FIG. 4A is a schematic side view showing a part of a power supply apparatus, and FIG. 4B is a schematic cross-sectional view along line IVB-IVB in FIG. 4A.

FIG. 5A is a schematic side view showing a part of a power supply apparatus according to a second embodiment of the present invention, and FIG. 5B is a schematic cross-sectional view along line VB-VB in FIG. 5A.

FIG. 6A is a perspective view showing a part of a printed circuit board and a heat dissipation plate of a power supply apparatus according to a fourth embodiment of the present invention, and FIG. 6B is a bottom view showing one of portions where the printed circuit board and the heat dissipation plate are joined together.

FIG. 7A is a schematic side view of a modification of an insert member of a power supply apparatus according to the fourth embodiment of the present invention, FIG. 7B is a schematic side view showing a state where a heat dissipation plate and the insert member are integrated into one piece and FIG. 7C is a schematic plan view showing a state where the integrated heat dissipation plate is provided to stand on a printed circuit board.

FIG. 8 is a schematic side view showing a part of a heat dissipation plate of a power supply apparatus according to the fourth embodiment.

FIG. 9A is a schematic cross-sectional view and FIG. 9B is a schematic plan view showing a state where a heat dissipation plate is fastened onto a printed circuit board with a screw in a power supply apparatus according to the fourth embodiment.

FIG. 10 is a schematic plan view showing a state where one heat dissipation plate is placed on a substrate in a conventional power supply apparatus.

### DESCRIPTION OF THE PREFERRED EMBODIMENTS

A power supply apparatus according to an embodiment of the present invention will be described hereinafter with reference to the drawings.

### First Embodiment

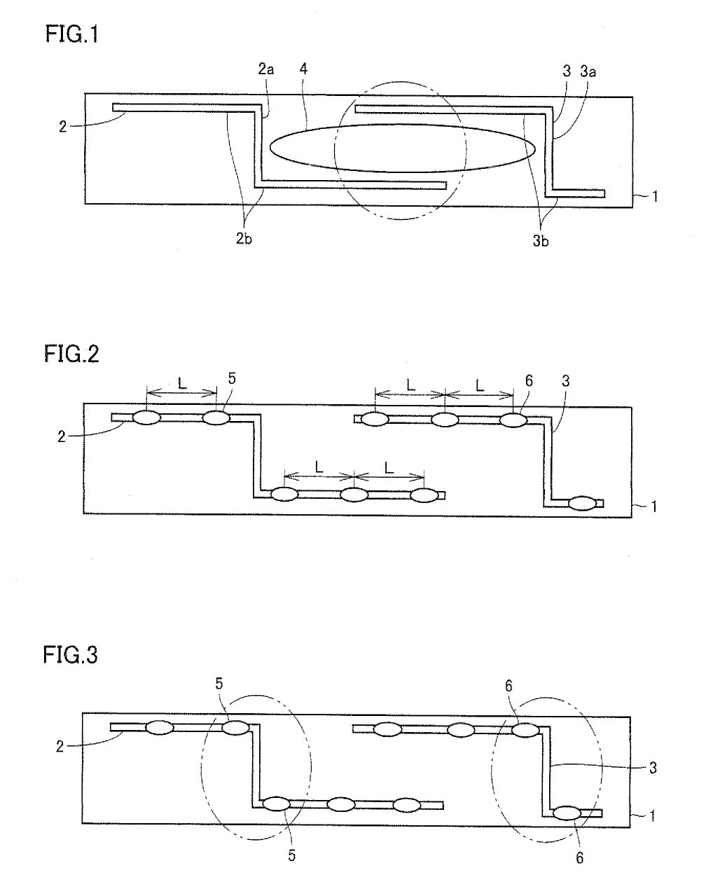

FIG. 1 is a schematic plan view showing arrangement of heat dissipation plates of a power supply apparatus according to a first embodiment of the present invention. As shown in FIG. 1, on an upper surface of a printed circuit board 1, a first heat dissipation plate 2 and a second heat dissipation plate 3 are provided to stand on the upper surface. A left region of printed circuit board 1 where first heat dissipation plate 2 is placed is a first region where an AC circuit component is mounted. A right region of printed circuit board 1 where second heat dissipation plate 3 is placed is a second region where a DC circuit component is mounted. As seen in the plan view, first heat dissipation plate 2 includes a linear first straight portion 2a and two second straight portions 2b extending respectively from the two ends of first straight portion 2a in respective directions opposite to each other. As seen in the plan view, second heat dissipation plate 3 also includes a linear first straight portion 3a and two second straight portions 3b extending respectively from the two ends of first straight portion 3a in respective directions opposite to each other. The heat dissipation plates are arranged in such a manner that at least a part of first straight portion 2a of first heat dissipation plate 2 and at least a part of first straight portion 3a of second heat dissipation plate 3 are opposite to each other, and at least a part of one of second straight portions 2b of first heat dissipation plate 2 and at least a part of one of second straight portions 3b of second heat dissipation plate 3 are opposite to each other. Second straight portions 2b of first heat dissipation plate 2 and second straight portions 3b of second heat dissipation plate 3 are each placed in the longitudinal direction of printed circuit board 1.

The heat dissipation plates are thus provided to stand on printed circuit board 1, and the heat dissipation plates can be arranged substantially uniformly over the whole region in the longitudinal direction and the direction perpendicular to the longitudinal direction of printed circuit board 1. Consequently, warpage of printed circuit board 1 can be effectively prevented by the stiffness of the heat dissipation plates. Further, since first and second heat dissipation plates 2, 3 are provided to stand on printed circuit board 1, the heat dissipation plates occupy a small area on printed circuit board 1. Accordingly, a large area can be ensured for mounting a chip-shaped component on printed circuit board 1. Furthermore, since first heat dissipation plate 2 and second heat dissipation plate 3 are provided as separate components, a heat generating component placed in the first region may be directly and electrically connected to first heat dissipation plate 2, and a heat generating component placed in the second region may be directly and electrically connected to second heat dissipation plate 3. In this case as well, first heat dissipation plate 2 and second heat dissipation plate 3 can be insulated from each other, and the heat can be efficiently released while the requirements of the Electrical Appliance and Material Safety Law are satisfied.

A structure for attaching the heat dissipation plates to printed circuit board 1 will be hereinafter described according to the present embodiment. FIG. 2 is a schematic plan view showing fixture portions where the heat dissipation plates and the printed circuit board of the power supply apparatus are joined to each other according to the present embodiment. Printed circuit board 1 is most unlikely to warp at the portions where the heat dissipation plates and printed circuit board 1 are joined to each other to be fixed to each other. In other words, at those portions where the heat dissipation plates and printed circuit board 1 are not fixed to each other, it is highly possible that printed circuit board 1 warps in a soldering process for soldering a component to be mounted to printed circuit board 1, for example. Therefore, if the heat dissipation plates and printed circuit board 1 are fixed to each other at an extremely small number of portions, printed circuit board 1 is likely to warp at the portions where the heat dissipation plates and printed circuit board 1 are not fixed to each other.

Warpage of the printed circuit board can be effectively prevented by providing, as shown in FIG. 2, fixture portions 5, 6 at an interval L of a few centimeters along the second straight portions of the heat dissipation plates. In the case where the heat dissipation plates and the printed circuit board are fixed to each other in this manner, warpage in the longitudinal direction of printed circuit board 1 is restricted and accordingly, warpage is more likely to occur in the direction perpendicular to the longitudinal direction. Then, in order to prevent warpage in the direction perpendicular to the longitudinal direction of printed circuit board 1, the heat dissipation plates and the printed circuit board may be fixed, as shown in FIG. 3, near the two ends of each first straight portion as enclosed by the chain double-dashed line in FIG. 3. Consequently, the first straight portion and printed circuit board 1 are more firmly integrated and warpage can be prevented more effectively. The heat dissipation plates and printed circuit board 1 may be joined at fixture portions 5, 6 by means of an adhesive, soldering or the like.

It is supposed that a component that generates noise is arranged in a noise generating component arrangement region 4 shown in FIG. 1. Since first heat dissipation plate 2 at a ground potential of the first region is provided between a power supply input portion and the noise generating component, the effect of preventing leakage of noise into the power supply input portion can be achieved. Specifically, noise generating component arrangement region 4 is the region on printed circuit board 1 enclosed by respective first straight portions 2a, 3a of first and second heat dissipation plates 2, 3 and one of second straight portions 2b of first heat dissipation plate 2 and one of second straight portions 3b of second heat dissipation plate 3. Further, the dimension of the section of second straight portion 2b of first heat dissipation plate 2 and the section of second straight portion 3b of second heat dissipation plate 3 that are opposite to each other as enclosed by the chain double-dashed line in FIG. 1 may be set to an appropriate dimension, so that the degree of the effect of lessening the noise by enclosing the noise that will be otherwise emitted to the outside, and the degree of the effect of releasing heat by ventilation can be adjusted relative to each other.

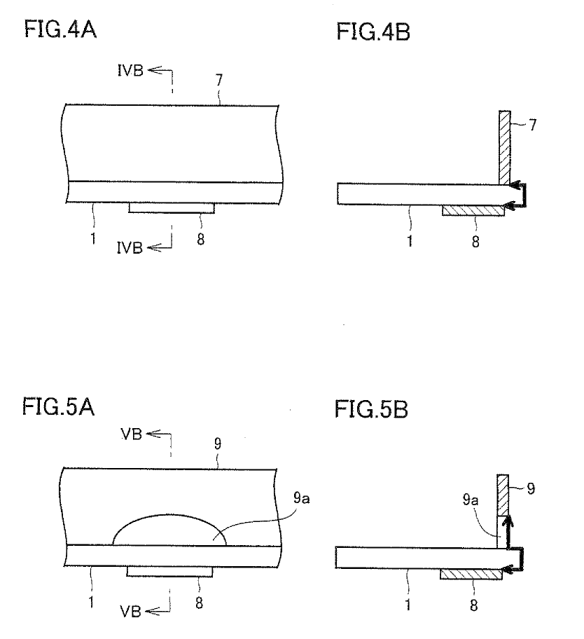

In order to make printed circuit board 1 unlikely to warp in both of the longitudinal direction and the direction perpendicular to the longitudinal direction, it is preferable that the second straight portion of the heat dissipation plate is located closer to the end along the longitudinal direction of printed circuit board 1. Here, a sufficient creepage distance between the heat dissipation plate and a circuit pattern formed on the lower surface of printed circuit board 1 could not be ensured depending on the case. As seen from FIG. 4B showing a cross section along line IVB-IVB in FIG. 4A, as a heat dissipation plate 7 is located closer to the end along the longitudinal direction of printed circuit board 1, the creepage distance between a circuit pattern 8 formed on the lower surface of printed circuit board 1 and heat dissipation plate 7 is shorter. in FIG. 4B, the distance between the two ends of the section indicated by the arrow-headed bold line is the creepage distance between circuit pattern 8 and heat dissipation plate 7. In order to maintain electrical insulation of heat dissipation plate 7 and circuit pattern 8 from each other, a predetermined creepage distance has to be ensured, In the power supply apparatus according to the present embodiment, heat dissipation plate 7 is placed closer to the end along the longitudinal direction of printed circuit board 1 while a sufficient creepage distance is ensured.

### Second Embodiment

A second embodiment of the present invention will be hereinafter described with reference to FIGS. 5A and 5B. In FIG. 5B, the distance between the two ends of the section indicated by the arrow-headed bold line is the creepage distance between a circuit pattern 8 and a heat dissipation plate 9. In the present embodiment, for the purpose of ensuring a sufficient creepage distance between heat dissipation plate 9 and circuit pattern 8, an opening 9a is provided as shown in FIG. 5A at an end, which abuts on printed circuit board 1, of heat dissipation plate 9, and at a position corresponding to the position where circuit pattern 8 is formed on the lower surface of printed circuit board 1. Opening 9a thus provided allows a sufficient creepage distance to be ensured in the cross section where circuit pattern 8 is provided as shown in FIG. 5B, and electrical insulation of heat dissipation plate 9 and circuit pattern 8 from each other can be maintained. In both of first and second heat dissipation plates, respective openings 9a may be formed, or opening 9a may be formed in one of the first and second heat dissipation plates. The shape of opening 9a is not limited to the semi-ellipse as shown in FIG. 5A, and another shape such as rectangle or triangle may be used as well. Other features are similar to those of the first embodiment, and the description thereof will not be repeated.

### Third Embodiment

A third embodiment of the present invention will be hereinafter described. It is supposed here that a heat generating component such as field-effect transistor is connected to a heat dissipation plate. Since the field-effect transistor switches rapidly, noise is generated. If the heat dissipation plate is electrically floated, the heat dissipation plate functions as an antenna and the noise is radiated to the outside via the heat dissipation plate. In this case, the potential of the heat dissipation plate may be made equal to a ground potential, so that the potential of the heat dissipation plate becomes stable and the noise of the field-effect transistor is less likely to be transmitted to the heat dissipation plate. Accordingly, radiation noise is reduced. Further, when the potential of the heat dissipation plate is equal to the ground potential, the heat dissipation plate can perform the function of grounding the printed circuit board. Consequently, the area of a ground pattern formed on the printed circuit board can be reduced, and the printed circuit board can be downsized or another chip-shaped component can be further mounted. In the power supply apparatus according to the present embodiment, the potential of the first heat dissipation plate is equal to a ground potential of the first region on the printed circuit board, and the potential of the second heat dissipation plate is equal to a ground potential of the second region on the printed circuit board. Other features are similar to those of the first embodiment, and the description thereof will not be repeated.

### Fourth Embodiment

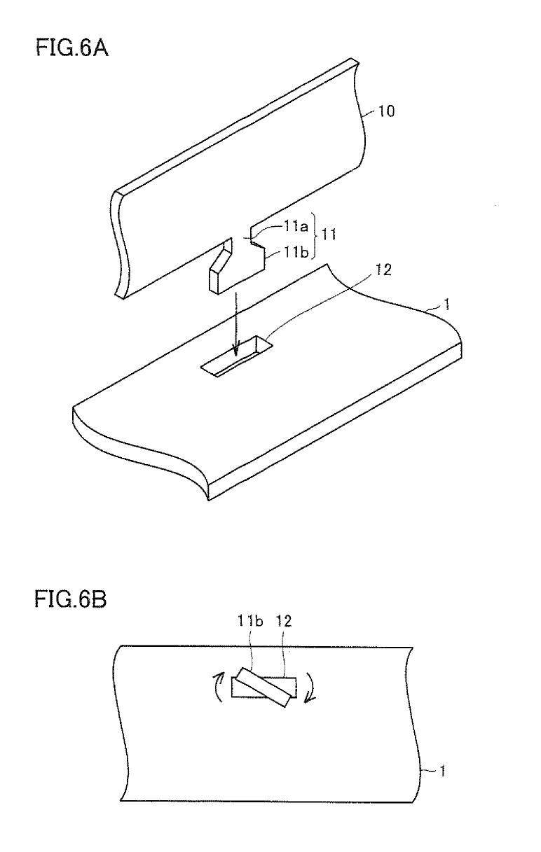

A fourth embodiment of the present invention will be hereinafter described. In the present embodiment, as shown in FIG. 6A, a heat dissipation plate 10 has an insert portion 11 on the end abutting on a printed circuit board 1. Insert portion 11 has a constricted portion 11a and has a protruded portion 11b at the extreme end as shown in FIG. 6A. In printed circuit board 1, a hole 12 is formed at the position corresponding to the position of insert portion 11 of heat dissipation plate 10. As shown in FIG. 6B, insert portion 11 of heat dissipation plate 10 is inserted in hole 12 of printed circuit board 1, and thereafter insert portion 11 and hole 12 are latched together so as to install heat dissipation plate 10 on printed circuit board 1. Specifically, insert portion 11 and hole 12 are latched together, namely engage to fasten, by twisting protruded portion 11b of insert portion 11 in the manner as shown in FIG. 6B. As the protruded portion of insert portion 11 is thus twisted to latch insert portion 11 and hole 12 together, heat dissipation plate 10 is accordingly drawn to printed circuit board 1, so that the heat dissipation plate and the printed circuit board can be firmly connected.

Insert portion 11 and hole 12 may also be latched together by soldering insert portion 11 to hole 12 in the state where insert portion 11 is fit in hole 12. In this case, the insert portion and the hole are not fastened by means of twisting, and it is unnecessary to provide constricted portion 11a to insert portion 11.

In order to make the potential of heat dissipation plate 10 equal to a ground potential, a circuit pattern of the ground potential may be provided around hole 12 on printed circuit board 1 and heat dissipation plate 10 may be connected to this circuit pattern, so that the potential of heat dissipation plate 10 is equal to the ground potential. The second heat dissipation plate may be connected to a ground pattern formed in the second region on the printed circuit board, so that radiation noise from the second heat dissipation plate can be reduced. Further, since the second heat dissipation plate also functions as a ground pattern, the area of a ground pattern formed in the second region on the printed circuit board can be reduced. Furthermore, the first heat dissipation plate may be connected to a ground pattern formed in the first region on the printed circuit board, and the second heat dissipation plate may be connected to a ground pattern formed in the second region on the printed circuit board, so that the radiation noise can be further reduced. In this case as well, respective areas of both of the ground pattern in the first region and the ground pattern in the second region can be reduced. In the case where the ground pattern of the second region is connected with a chassis (not shown), electrical inconvenience does not occur even if electrically conductive dust enters the chassis and the chassis and the ground pattern of the second region are short-circuited, since respective potentials of the chassis and the ground pattern of the second region are equal to each other. Thus, the reliability of the power supply apparatus can be enhanced.

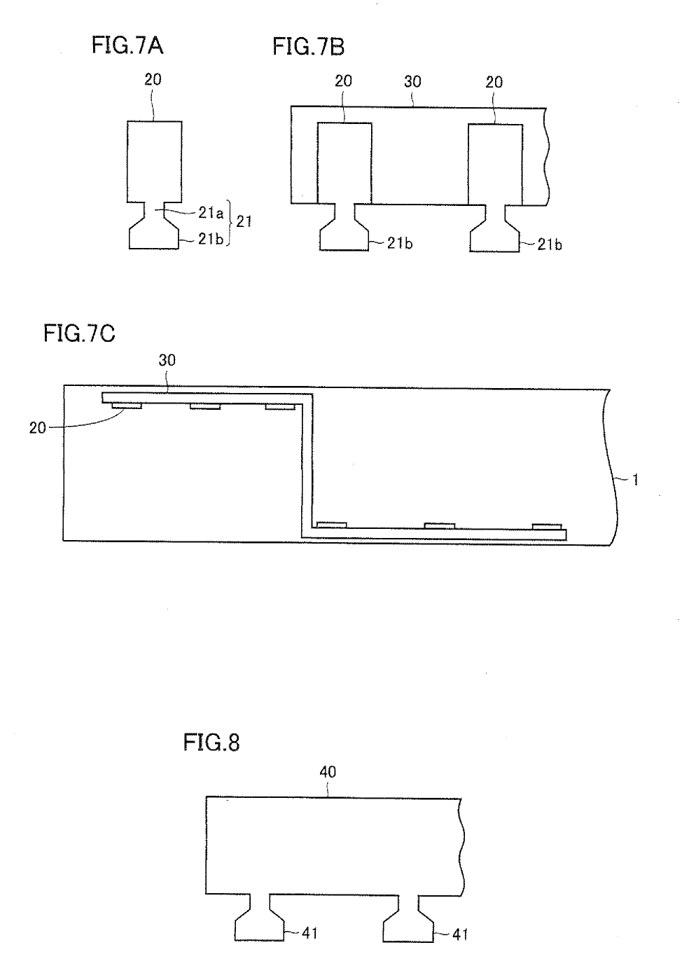

FIGS. 7A and 7B show a modification where an insert portion is provided separately from a heat dissipation plate of a power supply apparatus according to the fourth embodiment of the present invention. As shown in FIG. 7A, in an insert member 20, a constricted portion 21a is formed and a protruded portion 21b is formed at the extreme end, for example. As shown in FIG. 7B, a heat dissipation plate 30 and insert member 20 are joined together in such a manner that an insert portion 21 including constricted portion 21a and protruded portion 21b of insert member 20 extends from the end of heat dissipation plate 30 that abuts on printed circuit board 1. Heat dissipation plate 30 and insert member 20 are joined together by soldering, for example.

FIG. 7C shows the first heat dissipation plate, and the second heat dissipation plate is not shown. As shown in FIG. 7C, insert member 20 is formed with a smaller thickness than the first and second heat dissipation plates. Thus, the hole formed in the printed circuit board can be made smaller, and the space occupied by insert portions of heat dissipation plate 30 on the surface of printed circuit board 1 can be made smaller. As seen in the plan view, heat dissipation plate 30 is placed outside relative to insert member 20, so that heat dissipation plate 30 can be located closer to the end along the longitudinal direction on the printed circuit board 1. Thus, a larger area of the region can be provided for mounting a chip-shaped component.

FIG. 8 is a schematic side view showing a part of a heat dissipation plate 40 of a power supply apparatus according to the present embodiment. Preferably, a material for heat dissipation plate 40 is aluminum for example that is lightweight and highly workable. In the case where an insert portion 41 is provided as a separate member from heat dissipation plate 40, the material for insert portion 41 is preferably iron or the like having good solderability. Such a material can be used to easily solder a circuit pattern on printed circuit board 1 and insert portion 41, and electrical conduction is surely ensured.

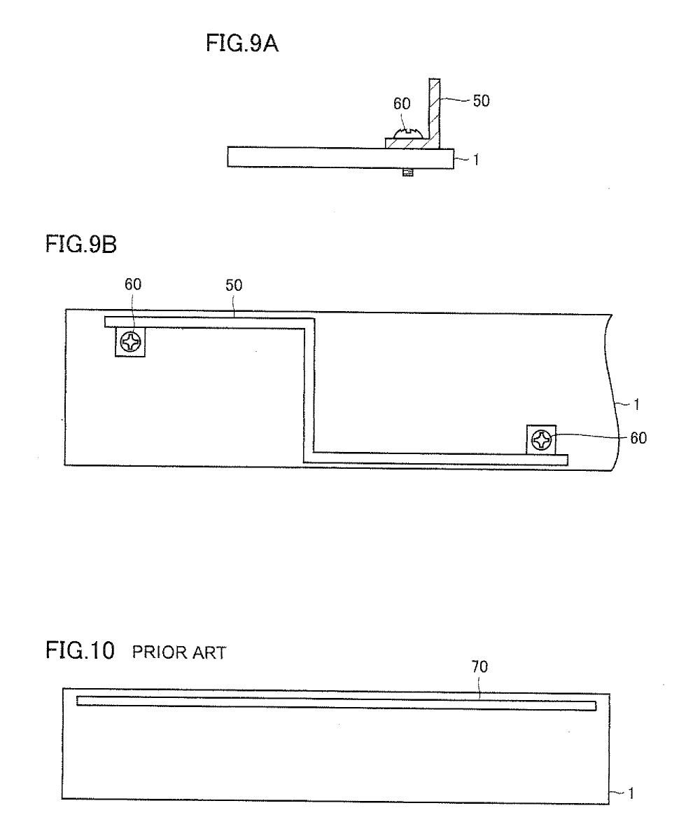

If a free space is left on printed circuit board 1, the heat dissipation plate may be connected with printed circuit board 1 using a screw 60 as shown in FIGS. 9A and 9B. A heat dissipation plate 50 shown in FIGS. 9A and 9B has a flat portion formed to have a hole for securing the screw therein, and a screw-tap is formed in printed circuit board 1. The flat portion and printed circuit board 1 are fastened together by means of screw 60 so that the flat portion and printed circuit board 1 closely attach to each other, Accordingly printed circuit board 1 and heat dissipation plate 50 are more firmly connected. Since other features are similar to those of the first embodiment, the description thereof will not be repeated.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A power supply apparatus for converting alternating current to direct current, comprising:
a printed circuit board including a first region where an alternating current circuit component is mounted and a second region where a direct current circuit component is mounted, and having a longitudinal direction;
a first heat dissipation plate provided to stand in said first region on said printed circuit board; and
a second heat dissipation plate provided to stand in said second region on said printed circuit board,
said first heat dissipation plate and said second heat dissipation plate each having a linear first straight portion and two second straight portions extending respectively from two ends of said first straight portion in respective directions opposite to each other as seen in a plan view, and
at least a part of said first straight portion of said first heat dissipation plate and at least a part of said first straight portion of said second heat dissipation plate being opposite to each other, at least a part of one of said second straight portions of said first heat dissipation plate and at least a part of one of said second straight portions of said second heat dissipation plate being opposite to each other, and said second straight portions each being placed in said longitudinal direction of said printed circuit board.

2. The power supply apparatus according to claim 1, wherein
said first heat dissipation plate is electrically connected to a heat generating component placed in said first region, and said second heat dissipation plate is electrically connected to a heat generating component placed in said second region.

3. The power supply apparatus according to claim 1, wherein
an opening is provided at an end abutting on said printed circuit board, of at least one of said first heat dissipation plate and said second heat dissipation plate, and said opening is located at a position corresponding to a position where a circuit pattern is formed on a rear surface of said printed circuit board.

4. The power supply apparatus according to claim 1, wherein
said first heat dissipation plate has a potential equal to a ground potential of said first region on said printed circuit board, and said second heat dissipation plate has a potential equal to a ground potential of said second region on said printed circuit board.

5. The power supply apparatus according to claim 1, wherein
insert portions are provided at respective ends abutting on said printed circuit board, of said first heat dissipation plate and said second heat dissipation plate, respectively,
holes are formed in said printed circuit board at respective positions corresponding to said insert portions, respectively, and
said first heat dissipation plate and said second heat dissipation plate are installed on said printed circuit board by latching together respective said insert portions and corresponding said holes, respectively.

6. The power supply apparatus according to claim 5, wherein
said insert portions are formed of respective insert members separate from and smaller in thickness than said first heat dissipation plate and said second heat dissipation plate, respectively, and
said first heat dissipation plate and said second heat dissipation plate are joined respectively to corresponding said insert members in such a manner that respective insert portions of said insert members extend from respective ends abutting on said printed circuit board, of said first heat dissipation plate and said second heat dissipation plate, respectively.

7. The power supply apparatus according to claim 1, wherein
a noise generating component generating electromagnetic noise is placed in a region on said printed circuit board, and said region is enclosed by respective said first straight portions of said first heat dissipation plate and said second heat dissipation plate and said one of said second straight portions of said first heat dissipation plate and said one of said second straight portions of said second heat dissipation plate.
